(19) United States
(12) Patent Application Publication
(10) Pub. No.: US 2009/0042145 A1
(43) Pub. Date: Feb. 12, 2009

(54) Method for Detecting Light Intensity Distribution for Gradient Filter and Method for Improving Line Width Consistency

(75) Inventors: Jinpo Yang, Shanghai (CN); Yuan Feng, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International (Shanghai) Corporation, Shanghai (CN)

(21) Appl. No.: 12/172,959

(22) Filed: Jul. 14, 2008

(30) Foreign Application Priority Data
Aug. 9, 2007 (CN) 200710044801.8

(51) Int. Cl. G03F 7/20

(52) U.S. Cl. 430/319

(57) ABSTRACT

A method for detecting light intensity distribution for a gradient filter, including: providing a mask plate which has patterns with identical line widths; providing a semiconductor substrate with a photosensitive material layer, and transferring the patterns of the mask plate to the photosensitive material layer, to form patterns of the photosensitive material layer; measuring line widths of the patterns of the photosensitive material layer at different positions on the semiconductor substrate, to obtain line width distribution of the patterns of the photosensitive material layer; inputting the measured line width distribution of the patterns of the photosensitive material layer into a function of light intensity distribution for a gradient filter versus line width distribution, to obtain light intensity distribution for the gradient filter. The present invention further provides a method for improving line width consistency in a photolithography process. The methods of the present invention are relatively simple, time-saving and cost-reducing.

### CROSS REFERENCE TO RELATED APPLICATION

This application is based on and claims the benefits from China Patent Application No. 200710044801.8, filed on Aug. 9, 2007, the disclosure of which is incorporated herein by reference.

### FIELD OF THE INVENTION

The present invention relates to the technical field of semiconductor manufacturing, and particularly to a method for detecting light intensity distribution for a gradient filter of an exposure device in a photolithography process and a method for improving line width consistency in a photolithography process.

### BACKGROUND OF THE INVENTION

Integrated circuits are formed on semiconductor wafers through a series of semiconductor manufacturing processes including deposition, photolithography, etching, ion implantation, chemical mechanical polishing, cleaning and the like. The photolithography process is designed to define areas for etching and ion implantation, and plays a major role in the semiconductor manufacturing processes. The integration level of semiconductor manufacturing depends on the standards of the photolithography. As the semiconductor manufacturing process develops towards smaller line width and higher integration level, higher demands have been presented for the photolithography process. The exposure devices have developed from step type to current scan type. In addition, high-transmissivity media-based immersion exposure devices have emerged. The wavelength of the light sources for exposure in the exposure devices has evolved from 365 nm to 248 nm, 193 nm, or even shorter, so as to meet the requirement for higher resolution in the photolithography process due to the increasingly reduced line width in the semiconductor manufacturing process.

An exposure device has been disclosed in U.S. Pat. No. 6,583,588 B2, a schematic diagram of the illumination system of which is shown in FIG. 1.

As shown in FIG. 1, the illumination system comprises a light source for exposure LA, shutters 11, 12, and 13, a diffractive optical element (DOE) 14, a beam adjusting lens 15, a zoom lens 16, a second diffractive optical element 18, a quartz bar 17, a prism 17a, a diaphragm 19, a condenser lens CO, a mirror 20, and a gradient filter 21.

When the shutters 11, 12, and 13 are in open state, a light beam emitted from the light source for exposure LA passes through the DOE 14, the beam adjusting lens 15, the zoom lens 16, the second DOE 18, the quartz bar 17, the prism 17a, the quartz bar 17, the diaphragm 19, the focus lens CO, the reflecting mirror 20, and the gradient filter 21 in sequence, and reaches the mask plate MA; then, the beam passes through the lens (not shown) below the mask plate MA and reaches the photoresist on a semiconductor substrate. Since the diaphragm 19 is smaller than the mask plate MA in the scan exposure machine, the mask plate must be moved in a direction (referred to as direction Y), so that the beam through the gradient filter 21 sweeps over the entire mask plate. Meanwhile, the semiconductor substrate must be moved in a direction opposite to the movement direction of the mask plate at a certain speed (the speed is equal to the moving speed of the MA multiplied by the magnification ratio of the lens below the MA), so as to transfer the entire pattern of the mask plate MA to the photoresist on the semiconductor substrate. The gradient filter is designed to regulate the light intensity distribution in the light path and compensate for the effect of aberration of the optical elements in the light path, so that the light emitted to the mask plate MA has a uniform intensity.

At present, the method for testing the gradient filter 21 includes: detecting the light intensity at different positions by means of a light intensity detector after the beam passes through the gradient filter 21, and determining the consistency of the light intensity at the different positions, so as to determine whether the gradient filter 21 meets the requirements of the processes. However, when the light intensity distribution for a gradient filter is tested by that method, the exposure device has to be shut down, and a detector has to be involved. Therefore, such a testing process is complicated and time-consuming. Especially, in a mass production plant where the gradient filter has to be tested periodically, such a testing process will reduce the up time of the exposure machine severely, thereby increasing the manufacturing cost.

### SUMMARY OF THE INVENTION

Embodiments of the present invention provide a method for detecting light intensity distribution for a gradient filter and a method for improving line width consistency in photolithography process, which are simple and time-saving.

According to an embodiment of the invention, a method for detecting light intensity distribution for a gradient filter comprises:

providing a mask plate, which has patterns with identical line widths;

providing a semiconductor substrate with a photosensitive material layer, and transferring the patterns of the mask plate to the photosensitive material layer by an exposure device, to form patterns of the photosensitive material layer;

measuring line widths of the patterns of the photosensitive material layer at different positions on the semiconductor substrate, to obtain line width distribution of the patterns of the photosensitive material layer; and

inputting the measured line width distribution of the patterns of the photosensitive material layer into a function of light intensity distribution for a gradient filter in an exposure device versus line width distribution, to obtain the light intensity distribution for the gradient filter.

Optionally, forming the patterns of the photosensitive material layer comprising:

loading the mask plate and semiconductor substrate into the exposure device;

switching on a light source for exposure, and selectively exposing the photosensitive material layer through the mask plate, to transfer the patterns of the mask plate to the photosensitive material layer;

performing a post exposure bake process for the semiconductor substrate after the exposure;

performing developing and flushing processes for the exposed area of the photosensitive material layer with a developer after the post exposure bake process; and

performing a hard bake process for the semiconductor substrate with the patterned photosensitive material layer after the developing and flushing processes.

Optionally, the exposure is scanning exposure or step exposure.

Optionally, if the exposure device is a step exposure device, the line width distribution is a planar distribution. If the exposure device is a scanning exposure device, the line width distribution is a linear distribution along a direction perpendicular to a scanning direction.

Optionally, the photosensitive material layer is formed by a photoresist.

Optionally, the photosensitive material layer is formed through spin-coating.

Optionally, the mask plate is a binary mask plate or a phase shift mask plate.

Optionally, the line widths of the patterns of the photosensitive material layer are measured by a scanning electron microscope.

According to another embodiment of the invention, a method for improving line width consistency in a photolithography process comprises:

providing a mask plate, which has patterns with identical line widths;

providing a first semiconductor substrate with a photosensitive material layer, and transferring the patterns of the mask plate to the photosensitive material layer by an exposure device, to form patterns of the photosensitive material layer;

measuring line widths of the patterns of the photosensitive material layer at different positions on the first semiconductor substrate, to obtain line width distribution of the patterns of the photosensitive material layer;

inputting the measured line width distribution of the patterns of the photosensitive material layer into a function of light intensity distribution for a gradient filter in an exposure device versus line width distribution, to obtain the light intensity distribution for the gradient filter;

obtaining a difference between the obtained light intensity distribution for the gradient filter in the exposure device forming the patterns of the photosensitive material layer and target light intensity distribution, from a difference between the measured line width distribution of the photosensitive material layer and target line width distribution;

providing a light intensity distribution regulating element in the exposure device, to reduce or eliminate the difference between the obtained light intensity distribution for the gradient filter and the target light intensity distribution; and

exposing a photosensitive material layer on a second semiconductor substrate by the exposure device with the light intensity distribution regulating element, to form patterns of the photosensitive material layer on the second semiconductor substrate.

Optionally, the light intensity distribution regulating element is a gradient filter or an adaptive optical element.

Optionally, the photosensitive material layer is formed by a photoresist.

Optionally, the photosensitive material layer is formed through spin-coating.

Optionally, the mask plate is a binary mask plate or a phase shift mask plate.

Optionally, the line widths of the patterns of the photosensitive material layer are measured by a scanning electron microscope.

Compared with the prior art, each of the above technical solutions has the following advantages.

The line width distribution of the patterns of the photosensitive material layer is measured, and thus the light intensity distribution for the gradient filter is obtained. Such a detection process is relatively simple and does not require halting the exposure device during the detection, thereby saving the time, improving the up time of the exposure device, and reducing the cost.

Moreover, when the gradient filter is tested periodically, the exposure device can continue working normally without wasting time, provided that the light intensity distribution meets the process requirements.

The detection can also be accomplished on-line, i.e., the line widths of the products that are produced by the exposure device normally can be sampling tested, and the light intensity distribution for the gradient filter can be calculated from the result of the sampling test, so as to ascertain the aging condition of the gradient filter.

The line width distribution of the patterns of the photosensitive material layer on the first semiconductor can be measured, and thereby the light intensity distribution for the gradient filter in the exposure device, as well as the difference between the light intensity distribution for the gradient filter and the target light intensity distribution, can be obtained. Further, the light intensity distribution regulating element can be added into the exposure device to compensate for the differences between the target line widths of the patterns and the measured line widths of the patterns of the photosensitive material layer resulting from the existing gradient filter, so as to improve the line width consistency of the patterns of the photosensitive material layer at different positions on the second semiconductor substrate.

### BRIEF DESCRIPTIONS OF THE DRAWINGS

FIG. 1 is a schematic diagram of an illumination system of an existing exposure device;

FIG. 2 is a flow diagram of a method for detecting light intensity distribution for a gradient filter in an exposure device according to an embodiment of the present invention;

FIG. 3 is a top view of a mask plate having patterns with identical line widths;

FIG. 4 is a top view of a semiconductor substrate with patterns of the photoresist;

FIG. 5 is an enlarged view of a shot of the patterns of the photoresist shown in FIG. 4; and

FIG. 6 is a flow diagram of a method for improving line width consistency in a photolithography process according to an embodiment of the present invention.

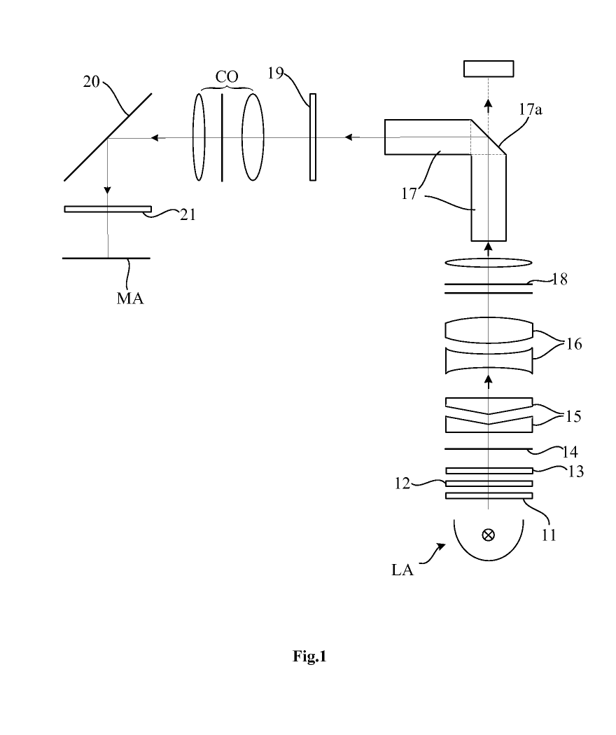

### DETAILED DESCRIPTIONS OF THE EMBODIMENTS

Hereinafter, the present invention will be further described in detail in conjunction with the embodiments thereof, with reference to the accompanying drawings.

In a photolithography process, the patterns of the mask plate must be duplicated precisely to the photosensitive material layer on the semiconductor substrate. As for the same mask plate, it is necessary for the patterns of the photosensitive material layer to have identical line widths after the patterns of the mask plate are transferred to the photosensitive material layer on the semiconductor substrate, i.e., it is desirable that the light from the light source is distributed uniformly to each sections on the mask plate after passing through the optical system in the exposure device.

Due to the effect of aberration in the optical system, after the patterns of the mask plate with identical line widths are transferred to the photosensitive material layer by means of exposure, the patterns formed on the photosensitive material layer do not have identical line widths. Especially, due to the fact that the aberration in the areas near the circumference of the optical lens in the optical system is more severe, after the patterns are transferred to the photosensitive material layer, the line widths of the patterns in the circumferential areas of the photosensitive material layer are much different from those of the patterns in the central areas of the photosensitive material layer. Even if a scanning exposure system is used, in the direction perpendicular to the scanning direction, the line widths of the patterns in the circumferential areas of the photosensitive material layer is still much different from those of the patterns in the central areas of the photosensitive material layer.

In order to reduce the effect of aberration in the optical system on the exposure process and improve line width consistency of the patterns of the semiconductor substrate, a gradient filter is added between the illumination system of the optical system and the mask plate, so as to improve the light intensity distribution on the mask plate and compensate for the effect of aberration. The gradient filter has different light transmissivity at different positions. In other words, a beam of light with a first light intensity distribution before it passes through the gradient filter will change in light intensity distribution and thereby has a second light intensity distribution after it passes through the gradient filter. The gradient filter is designed to have different transmissivity at different position so as to obtain the required light intensity distribution. In the optical exposure system required by semiconductor manufacturing process, the gradient filter is mainly designed to improve line width consistency that is degraded by the effect of aberration in the optical system.

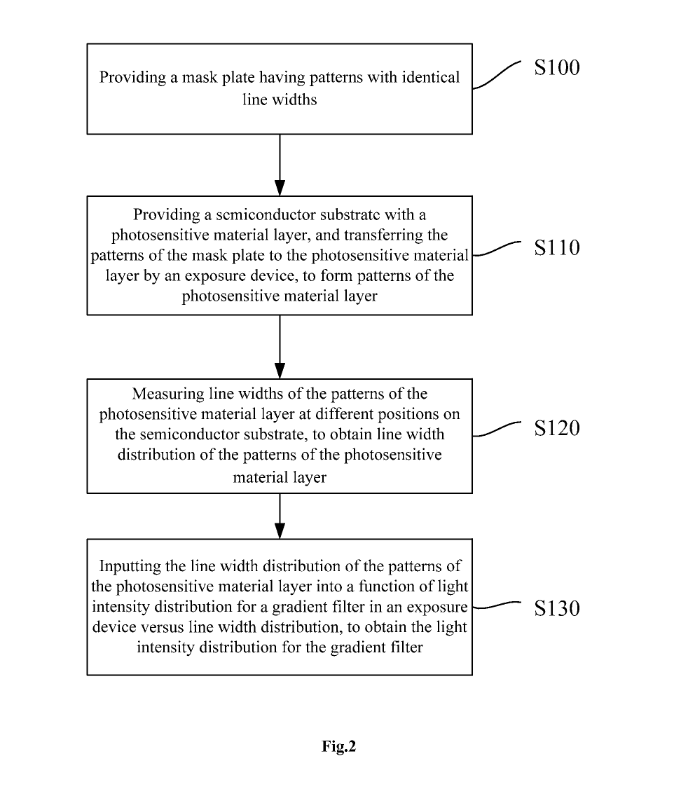

The present invention provides a method for detecting light intensity distribution for a gradient filter in an exposure device. FIG. 2 is a flow diagram of a method for detecting light intensity distribution for a gradient filter in an exposure device according to an embodiment of the present invention.

As shown in FIG. 2, in step S100, a mask plate is provided, which has patterns with identical line widths.

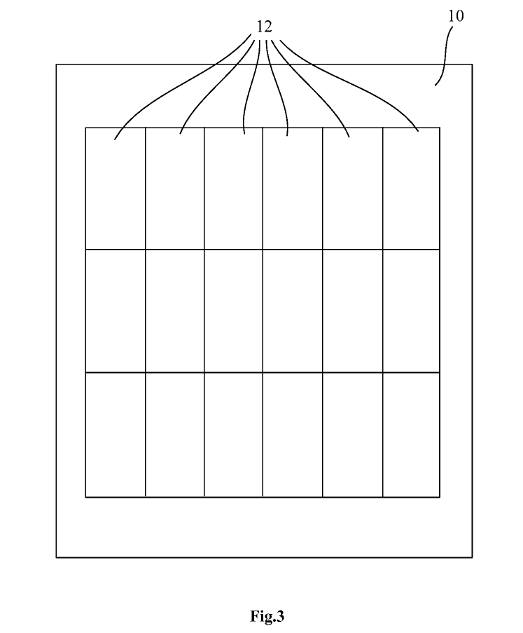

As shown in the front view in FIG. 3, a mask plate 10 is provided. The mask plate 10 can be a binary mask plate or a phase shift mask plate, having a plurality of chip patterns 12 with identical line widths at corresponding positions. The patterns can be patterns for forming lines, trenches, or holes.

In step S110, a semiconductor substrate with a photosensitive material layer is provided. The patterns of the mask plate are transferred to the photosensitive material layer by means of an exposure device, to form patterns of the photosensitive material layer.

The semiconductor substrate may be a bare wafer with a flat and smooth surface, so as to reduce the effect of surface flatness on the line widths of subsequently formed patterns.

The semiconductor substrate may have other semiconductor devices or structures. Before the photosensitive material layer is formed on the semiconductor substrate, an anti-reflection layer can be coated on the semiconductor substrate first to flatten the surface of the semiconductor substrate.

The photosensitive material layer can be formed by a photoresist, which can be a positive photoresist or negative photoresist. In the present embodiment, the photoresist is a positive photoresist.

The photoresist is formed on the semiconductor substrate through the following steps.

First, the semiconductor substrate is cleaned and dehydrated. A layer of Hexa Methyl DiSilazane (HMDS) is then coated on the semiconductor substrate at a certain temperature to change the hydrophilic or hydrophobic property of the surface of the semiconductor substrate, thereby increasing the adhesiveness of the subsequently spin-coated photoresist to the surface of the semiconductor substrate.

Next, the semiconductor substrate is cooled to the room temperature. The cooling process can be carried out on the cold plate of the spin-coating device.

Subsequently, the semiconductor substrate is loaded to a wafer chuck which has a vacuum chuck designed to adhere the semiconductor substrate to the wafer chuck.

The nozzle of Resist Reduction Consumption (RRC) is moved to above the central part of the semiconductor substrate and is driven to spray RRC to the surface of the semiconductor substrate.

The wafer chuck revolves to drive the semiconductor substrate to revolve at a low speed, so that the RRC flows outwards along the surface of the semiconductor substrate. RRC spraying is then halted. Next, the photoresist nozzle is moved to above the central part of the semiconductor substrate and is driven to spray the photoresist, while the semiconductor substrate is kept revolving, so that the photoresist spreads on the surface of the RRC under a centrifugal force and covers the entire surface of the semiconductor substrate. A photoresist layer having a certain thickness in a good uniformity is formed on the surface of the semiconductor substrate by regulating the revolution speed of the semiconductor substrate, wherein the RRC is applied to reduce the resistance for the photoresist flowing on the surface of the semiconductor substrate, and thereby is helpful to reduce the consumption of the photoresist.

After the photoresist is spin-coated, the semiconductor substrate with the photoresist is soft baked, to remove the solvent in the photoresist layer and enhance adhesiveness of the photoresist layer to the surface of the semiconductor substrate.

After the photoresist layer is formed on the semiconductor substrate, the semiconductor substrate is loaded to the wafer chuck of the exposure device, and the mask plate 10 is loaded on the reticle stage of the exposure device.

The mask plate 10 is aligned to the semiconductor substrate with reference to the alignment marks (not shown) of the mask plate 10 and that of the semiconductor substrate. The light source for exposure is then switched on to expose the photoresist layer on the semiconductor substrate by means of the light that has passed though the optical system and the mask plate 10, so as to transfer the patterns of the mask plate 10 to the photoresist layer.

The exposure device can be a scanning exposure device or step exposure device.

In the case of a step exposure device, the patterns of the mask plate can be transferred completely to the photoresist layer on the semiconductor substrate by means of a single exposure. Meanwhile, the semiconductor substrate is moved at a certain step length to expose the photoresist layer at different positions on the semiconductor substrate.

In the case of a scanning exposure device, due to the fact that the diaphragm in the optical system is smaller than the mask plate, the mask plate must be moved in a direction (referred to as direction Y), so that the light beams that have passed through the diaphragm and the gradient filter behind the diaphragm can sweep over the entire mask plate and project to the photoresist layer on the semiconductor substrate. Meanwhile, the semiconductor substrate must be moved at a certain speed in the direction opposite to the moving direction of the mask plate, so that the patterns of the entire mask plate can be transferred to the photoresist layer on the semiconductor substrate.

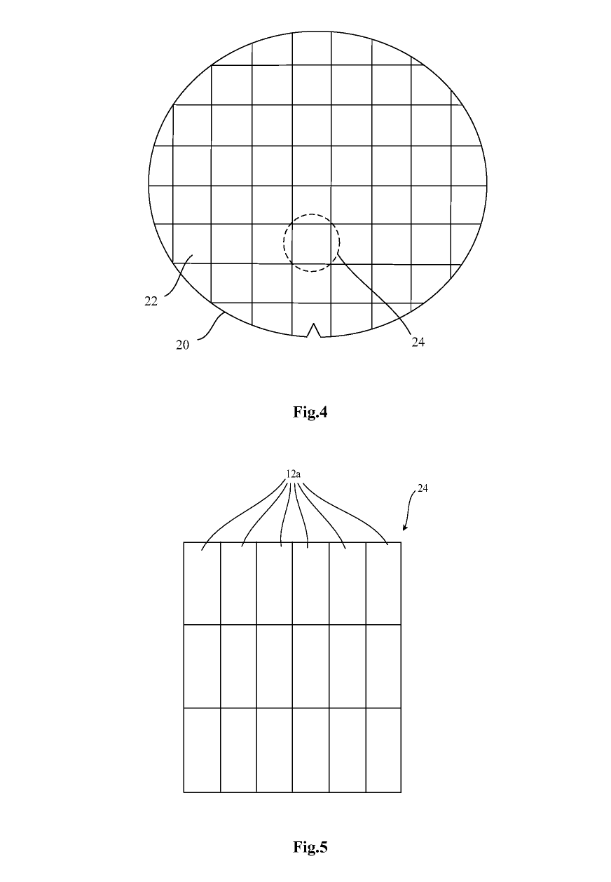

Taking the case of scanning exposure for instance, after one scanning process, patterns corresponding to the patterns of the entire mask plate are formed on the photoresist layer on the semiconductor substrate (referred to as a shot or field). Next, scanning exposure is carried out on the photoresist layer at other positions on the semiconductor substrate, till the entire photoresist layer on the semiconductor substrate has been exposed and forms a plurality of shots. As shown in the schematic diagram in FIG. 4, a plurality of shots 22 are formed in the photoresist layer on the semiconductor substrate 20. The patterns of each shot 22 correspond to the patterns of the entire mask plate. In other words, each shot 22 has a plurality of chip patterns 12a. FIG. 5 shows a magnified view of a shot 24.

After the patterns are formed in the photoresist layer on the semiconductor substrate, the semiconductor substrate is treated through a post exposure bake (PEB) process. A PEB process, on one hand, can eliminate the standing wave effect upon exposure (mainly for I-Line photoresist), and on the other hand, can accelerate the catalyzed reaction of photo-acid (mainly for chemical amplified photoresist), so that the exposed photoresist generates a substance that is soluble in the developer.

Following the PEB process, the photoresist layer is developed by the developer. For a positive photoresist, the photoresist in the exposed area is removed, and then the semiconductor substrate is flushed with deionized water.

After developing and flushing, the semiconductor substrate is hard baked, so as to increase the adhesiveness of the patterned photoresist to the semiconductor substrate.

In step S120, the line widths of the patterns of the photosensitive material layer are measured at different positions on the semiconductor substrate, so as to obtain the line width distribution of the patterns of the photosensitive material layer.

In the case of a step exposure device, the patterns of the entire mask plate can be transferred to the photoresist layer by means of a single exposure and form a shot. The light transmissivity at different positions of the gradient filter in the exposure device has specific effect on the line widths of the patterns of the photoresist at different positions within a shot, thus the line width distribution within a shot reflects the light transmissivity distribution (referred to as light intensity distribution) at different positions of the gradient filter. To obtain the light intensity distribution for a gradient filter in a step exposure device, the line widths of the patterns of the photoresist at different positions within a shot must be measured, and thereby the planar distribution of line width within the entire shot is obtained.

In the case of a scanning exposure device, the gradient filter has a smaller width in the scanning direction and a larger width (close to the size of the mask plate) in the direction perpendicular to the scanning direction (direction X). In addition, due to the fact that the light transmissivity of the gradient filter has little change or no change in the scanning direction (direction Y) but changes (increases or decreases) gradually from the center to the circumference in direction X, the line width distribution along direction X within a shot can reflect the light transmissivity distribution of the gradient filter at different positions. Therefore, it is necessary for the line widths at different positions within a shot in direction X to be measured, so as to obtain the linear distribution of line width in direction X.

In an embodiment, the line widths of the patterns of the photoresist layer are measured by a scanning electron microscope (SEM).

In step S130, the measured line width distribution of the patterns of the photosensitive material layer is inputted into a function of light intensity distribution for a gradient filter in an exposure device versus line width distribution, to obtain the light intensity distribution for the gradient filter.

Since the gradient filter is used in the exposure device to improve light intensity distribution in the optical system and obtain required light intensity distribution on the mask plate, so as to improve the light intensity distribution on the photoresist layer after the light passes through the mask plate and form patterns with good line width consistency on the photoresist layer. Thus, the light intensity distribution for a gradient filter has a functional relationship with the line width distribution of the patterns of the photoresist layer after the light beams pass through the gradient filter. After the line width distribution of the patterns of the photoresist layer is obtained, it can be inputted into the function to obtain the light intensity distribution for the gradient filter. The functional relationship between light intensity distribution for a gradient filter and line width distribution of patterns is provided by the gradient filter manufacturer or can be obtained through repeated measurements.

When the exposure device operates, the energy of the light source for exposure is powerful and may cause the aging of the gradient filter, and thus results in the change of light transmissivity of the gradient filter. As a result, the light intensity distribution for the gradient filter will deviate from the target light intensity distribution. Therefore, the light intensity distribution for the gradient filter must be checked periodically. However, in the prior art, the light intensity distribution is detected with a light intensity detector, which requires halting the exposure device. Furthermore, the testing process is complicated and time-consuming, and thereby it reduces the up time of the exposure device and increases the depreciation cost of the exposure device.

With the method described in present embodiment, the patterns with identical line widths are arranged on the mask plate, and, if the light intensity distribution for the gradient filter meets the requirement, after the light beams pass through the exposure system and form patterns of the photoresist, the patterns of the photoresist corresponding to the patterns with identical line widths on the mask plate will have identical or almost identical line widths. If the gradient filter is aged or there are other problems that affect light intensity distribution, the patterns of the photoresist corresponding to the patterns with identical line widths on the mask plate will no longer have identical line widths. This means that the line width distribution of the resulting patterns of the photoresist obtained by providing patterns with identical line widths on the mask plate directly reflects the light intensity distribution for the gradient filter, and, by measuring the line width distribution of the patterns of the photoresist, the light intensity distribution for the gradient filter can be obtained. Such a detecting process is relatively simple, and does not require halting the exposure device, and thereby it can save time, improve the up time of the exposure device, and reduce the cost.

Moreover, when the gradient filter is tested periodically, the exposure device can continue working normally without wasting time, provided that the light intensity distribution meets the process requirements.

The detection can also be accomplished in-line, i.e., the line widths of the products that are produced by the exposure device normally can be sampling tested, and the light intensity distribution for a gradient filter can be calculated from the result of the sampling test, so as to ascertain the aging status of the gradient filter.

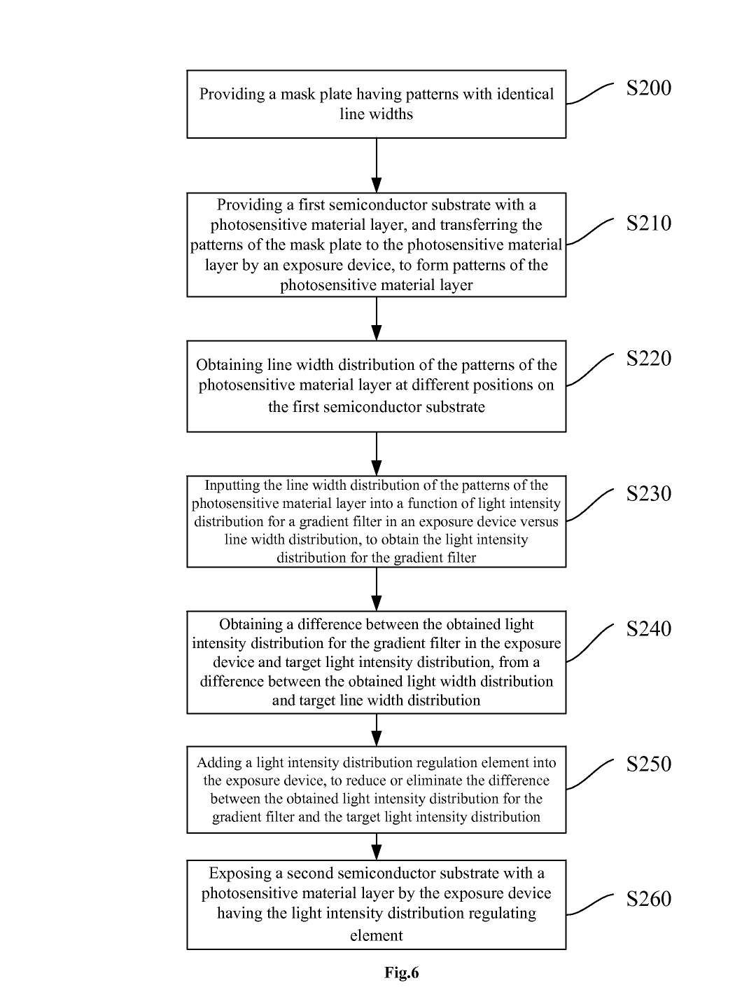

The present invention further provides a method for improving line width consistency in a photolithography process. FIG. 6 is a flow diagram of a method for improving line width consistency in a photolithography process according to an embodiment of the present invention.

As shown in FIG. 6, in step S200, a mask plate having patterns with identical line widths is provided. The mask plate is a binary mask plate or a phase shift mask plate.

In step S210, a first semiconductor substrate with a photosensitive material layer is provided, and the patterns of the mask plate is transferred by means of an exposure device to the photosensitive material layer, forming patterns of the photosensitive material layer. The photosensitive material layer can be formed by a photoresist through spin coating.

In step S220, the line widths of the patterns of the photosensitive material layer are measured at different positions on the first semiconductor substrate, so as to obtain the line width distribution of the patterns of the photosensitive material layer.

The line widths of the patterns of the photosensitive material layer are measured by a scanning electron microscope (SEM).

In step S230, the measured line width distribution of the patterns of the photosensitive material layer is inputted into a function of light intensity distribution for a gradient filter in an exposure device versus line width distribution, to obtain the light intensity distribution for the gradient filter.

In step S240, the difference between the light intensity distribution for the gradient filter in the exposure device forming the patterns of the photosensitive material layer and the target light intensity distribution is obtained, from the difference between the measured line width distribution of the photosensitive material layer and the target line width distribution.

In step S250, a light intensity distribution regulating element is added into the exposure device, to reduce or eliminate the difference between the light intensity distribution for the gradient filter and the target light intensity distribution.

The light intensity distribution regulating element is a gradient filter or an adaptive optical element.

In step S260, a photosensitive material layer on a second semiconductor substrate is exposed by the exposure device mounted with the light intensity distribution regulating element, forming patterns of the photosensitive material layer on the second semiconductor substrate.

By measuring the line width distribution of the patterns of the photoresist on the first semiconductor, the light intensity distribution for the gradient filter in the exposure device, as well as the difference between the light intensity distribution for the gradient filter and the target light intensity distribution, can be obtained. The light intensity distribution regulating element is then added into the exposure device to compensate for the difference between the target line width and the measured line width of the patterns of the photoresist resulting from the existing gradient filter, so as to improve the consistency of line widths of the patterns of the photoresist layer at different positions on the second semiconductor substrate.

The present invention has been disclosed with reference to, but not limited to, the above preferred embodiments. Various variations and modifications can be made by the skilled in the art without departing from the spirit and scope of the present invention, the protection scope of which is thus to be defined by the appended claims.

What is claimed is:

1. A method for detecting light intensity distribution for a gradient filter, comprising:
providing a mask plate, which has patterns with identical line widths;
providing a semiconductor substrate with a photosensitive material layer, and transferring the patterns of the mask plate to the photosensitive material layer by an exposure device, to form patterns in the photosensitive material layer;
measuring line widths of the patterns of the photosensitive material layer at different positions on the semiconductor substrate, to obtain line width distribution of the patterns of the photosensitive material layer; and
inputting the measured line width distribution of the patterns of the photosensitive material layer into a function of light intensity distribution for a gradient filter in an exposure device versus line width distribution, to obtain the light intensity distribution for the gradient filter.

2. The method of claim 1, wherein forming the patterns of the photosensitive material layer comprises:
loading the mask plate and the semiconductor substrate into the exposure device;
switching on a light source for exposure, and selectively exposing the photosensitive material layer through the mask plate, to transfer the patterns of the mask plate to the photosensitive material layer;
performing a post exposure bake process for the semiconductor substrate after the exposure;
performing developing and flushing processes for the exposed area of the photosensitive material layer with a developer after the post exposure bake process; and
performing a hard bake process for the semiconductor substrate after the developing and flushing processes.

3. The method of claim 2, wherein the exposure is scanning exposure or step exposure.

4. The method of claim 1, wherein, if the exposure device is a step exposure device, the line width distribution is a planar distribution; if the exposure device is a scanning exposure device, the line width distribution is a linear distribution along a direction perpendicular to a scanning direction.

5. The method of claim 1, wherein the photosensitive material layer is formed by a photoresist.

6. The method of claim 5, wherein the photosensitive material layer is formed through spin coating.

7. The method of claim 1, wherein the mask plate is a binary mask plate or a phase shift mask plate.

8. The method of claim 1, wherein the line widths of the patterns of the photosensitive material layer are measured by means of a scanning electron microscope.

9. A method for improving line width consistency in a photolithography process, comprising:
providing a mask plate, which has patterns with identical line widths;
providing a first semiconductor substrate with a photosensitive material layer, and transferring the patterns of the mask plate to the photosensitive material layer by an exposure device, to form patterns of the photosensitive material layer;
measuring line widths of the patterns of the photosensitive material layer at different positions on the first semiconductor substrate, to obtain line width distribution of the patterns of the photosensitive material layer;
inputting the measured line width distribution of the patterns of the photosensitive material layer into a function of light intensity distribution for a gradient filter in an exposure device versus line width distribution, to obtain the light intensity distribution for the gradient filter;
obtaining a difference between the obtained light intensity distribution for the gradient filter in the exposure device forming the patterns of the photosensitive material layer and target light intensity distribution, from a difference between the measured line width distribution of the photosensitive material layer and target line width distribution;
providing a light intensity distribution regulating element in the exposure device, to reduce or eliminate the difference between the obtained light intensity distribution for the gradient filter and the target light intensity distribution; and
exposing a photosensitive material layer on a second semiconductor substrate using the exposure device with the light intensity distribution regulating element to form patterns of the photosensitive material layer on the second semiconductor substrate.

10. The method of claim 9, wherein the light intensity distribution regulating element is a gradient filter or an adaptive optical element.

11. The method of claim 9, wherein the photosensitive material layer is formed by a photoresist.

12. The method of claim 11, wherein the photosensitive material layer is formed through spin coating.

13. The method of claim 9, wherein the mask plate is a binary mask plate or a phase shift mask plate.

14. The method of claim 9, wherein the line widths of the patterns of the photosensitive material layer are measured by a scanning electron microscope.
